(19) United States
(12) Patent Application Publication
(10) Pub. No.: US 2017/0270656 A1
(43) Pub. Date: Sep. 21, 2017

(54) METHOD FOR INSPECTING BLANKING PLATE

(71) Applicant: NuFlare Technology, Inc., Yokohama-shi (JP)

(72) Inventor: Ryosuke UEBA, Yokohama-shi (JP)

(73) Assignee: NuFlare Technology, Inc., Yokohama-shi (JP)

(21) Appl. No.: 15/425,547

(22) Filed: Feb. 6, 2017

(30) Foreign Application Priority Data
Mar. 16, 2016 (JP) 2016-052527

(51) Int. Cl. G06T 7/00; G03F 7/40; G06K 9/62

(52) U.S. Cl. CPC G06T 7/0004; G06K 9/6202; G03F 7/40; G06T 2207/30148

(57) ABSTRACT

In one embodiment, a method for inspecting a blanking plate includes generating a plurality of beams by causing a charged particle beam to pass through a shaping aperture array having a plurality of holes, performing blanking deflection on the plurality of beams by using a plurality of blankers provided in a blanking plate, each of the plurality of blankers corresponding to one of the plurality of beams, writing a first inspection pattern on a substrate by using a first writing mode in which beams that have not been deflected by the plurality of blankers are radiated onto the substrate, writing a second inspection pattern on the substrate by using a second writing mode in which beams that have been deflected by the plurality of blankers are radiated onto the substrate, obtaining a pattern image of the first inspection pattern and a pattern image of the second inspection pattern, the first and second inspection patterns having been formed on the substrate, and determining a defect by comparing the obtained pattern images.

### CROSS REFERENCE TO RELATED APPLICATION

This application is based upon and claims benefit of priority from the Japanese Patent Application No. 2016-52527, filed on Mar. 16, 2016, the entire contents of which are incorporated herein by reference.

### FIELD

The present invention relates to a method for inspecting a blanking plate that performs blanking of multi-charged particle beams.

### BACKGROUND

Along with an improvement in integration of LSIs, circuit line widths of semiconductor devices have become finer. As an example of a method for forming exposure masks (exposure masks used in steppers and scanners are also called reticles) that are used for forming circuit patterns in such semiconductor devices, an electron-beam writing technology having high resolution has been used.

For example, there is a writing apparatus using multibeams. Numerous beams can be radiated at a time (at one shot) by using multibeams, and thus, an improvement in throughput can be achieved compared with the case of performing writing by using one electron beam. In a multi-beam writing apparatus, for example, multibeams are formed by causing an electron beam emitted from an electron gun to pass through a shaping aperture array having a plurality of holes, and blanking control of each of the beams is performed by a blanking plate. The beams that are not blocked are radiated onto desired locations on a sample.

Passage holes through which the beams pass are formed in the blanking plate in such a manner as to correspond to the positions at which the holes of the shaping aperture array are located. Blankers are each disposed at a corresponding one of the passage holes, each of the blankers being formed of two electrodes that are paired with each other. By controlling a voltage to be applied to each of the blankers, the electron beams that pass through the passage holes are deflected independently of one another, and blanking control is performed.

When one of blankers has a defect, and a desired voltage cannot be applied to the blanker, there is a case where switching a corresponding one of beams on and off cannot be performed, and there is a case where the beam cannot be radiated onto a desired location, which in turn results in deterioration of writing accuracy. Therefore, it is necessary to determine which blanker has a defect. However, multibeams are formed of a large number of beams, and consequently, there has been a problem in that it takes a long time to determine a defective portion from the writing result of each of the beams.

### BRIEF DESCRIPTION OF THE DRAWINGS

FIG. 1 is a schematic diagram of a writing apparatus according to an embodiment of the present invention.

FIG. 2 is a plan view of a shaping aperture array.

FIG. 3A is a diagram illustrating an example of beam radiation in a voltage-off beam-radiation mode, and FIG. 3B is a diagram illustrating an example of beam radiation in the voltage-on beam-radiation mode.

FIG. 4 is a flowchart illustrating an inspection method according to the embodiment.

FIG. 5 is a diagram illustrating an irradiation region of multibeams.

FIG. 6 is a diagram illustrating a method of writing an inspection pattern.

FIG. 7A to 7C are schematic diagrams of inspection patterns, and FIG. 7D is a schematic diagram of a design pattern.

FIG. 8 is a diagram illustrating an example of a defect that is detected.

FIG. 9 is a diagram illustrating an example of a defect that is detected.

FIG. 10 is a diagram illustrating an example of beam radiation in the case where a blanker has a defect.

FIG. 11 is a diagram illustrating an example of a defect that is detected.

FIG. 12A is a diagram illustrating an example of beam radiation in the case where there is no defect in blankers, and FIG. 12B is a diagram illustrating an example of beam radiation in the case where one of the blankers has a defect.

### DETAILED DESCRIPTION

In one embodiment, a method for inspecting a blanking plate includes generating a plurality of beams by causing a charged particle beam to pass through a shaping aperture array having a plurality of holes, performing blanking deflection on the plurality of beams by using a plurality of blankers provided in a blanking plate, each of the plurality of blankers corresponding to one of the plurality of beams, writing a first inspection pattern on a substrate by using a first writing mode in which beams that have not been deflected by the plurality of blankers are radiated onto the substrate, writing a second inspection pattern on the substrate by using a second writing mode in which beams that have been deflected by the plurality of blankers are radiated onto the substrate, obtaining a pattern image of the first inspection pattern and a pattern image of the second inspection pattern, the first and second inspection patterns having been formed on the substrate, and determining a defect by comparing the obtained pattern images.

An embodiment of the present invention will be described below with reference to the drawings.

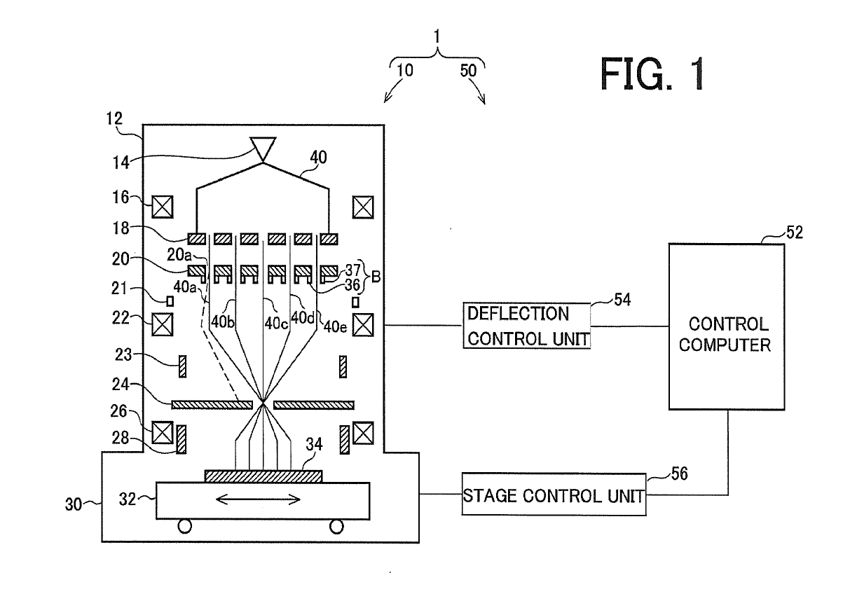

FIG. 1 is a schematic diagram of a writing apparatus according to an embodiment of the present invention. A writing apparatus 1 illustrated in FIG. 1 is a multi-charged-particle-beam writing apparatus that includes a writing unit 10, which writes a desired pattern by radiating electron beams onto a target such as a mask or a wafer, and a control unit 50, which controls the operation of the writing unit 10.

The writing section 10 includes an electron-beam lens barrel 12 and a writing chamber 30. In the electron-beam lens barrel 12, an electron gun 14, an illumination lens 16, a shaping aperture array 18, a blanking plate 20, an alignment portion 21, a reducing lens 22, a deflector 23, a limiting aperture member 24, an objective lens 26, and a deflector 28 are disposed.

A stage 32 is disposed in the writing chamber 30. The stage 32 is a stage that is a combination of an XY-axis stage and a Z-axis stage. A writing-target substrate 34 is placed on the stage 32. The writing-target substrate includes, for example, a wafer and an exposure mask that is used for transferring a pattern onto a wafer by using a step-and-repeat exposure apparatus, such as a stepper or a scanner that uses an excimer laser as a light source or an extreme ultraviolet exposure apparatus. In addition, the writing-target substrate includes a mask on which a pattern has been previously formed. For example, in the case of a Levenson-type mask, a writing operation needs to be performed twice, and thus, a writing operation for a second pattern may sometimes be performed on a member that has been processed into a mask after a writing operation has been performed once thereon.

The control unit 50 includes a control computer 52, a deflection control unit 54, and a stage control unit 56. At least a portion of the control computer 52, the deflection control unit 54, and the stage control unit 56 may be formed of hardware or may be formed of software. In the case where the at least a portion of the control computer 52, the deflection control unit 54, and the stage control unit 56 is formed of software, a program that realizes at least part of its functions may be stored in a recording medium, such as a flexible disk or a CD-ROM, and the program may be run by loading the program into a computer, which includes an electric circuit. The recording medium is not limited to a removable recording medium, such as a magnetic disk or an optical disc, and may be a fixed-type recording medium, such as a hard disk device or a memory.

In the electron-beam lens barrel 12, an electron beam 40 emitted from the electron gun 14 is caused by the illumination lens 16 to substantially perpendicularly illuminate the entire shaping aperture array 18 for forming multibeams.

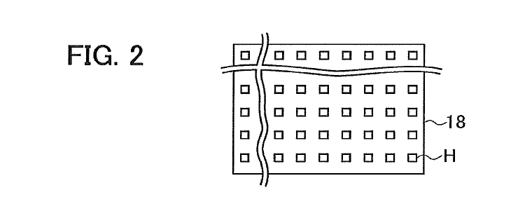

FIG. 2 is a plan view of the shaping aperture array 18. As illustrated in FIG. 2, a plurality of holes (openings) H are formed in the shaping aperture array 18 in such a manner as to be arranged in a matrix at a predetermined arrangement pitch in the longitudinal direction (Y direction) and the lateral direction (X direction). The holes H are formed in rectangular shapes having the same design dimensions. As a result of the electron beam 40 passing through the plurality of the holes H, multibeams 40a to 40e such as those illustrated in FIG. 1 are formed.

Passage holes 20a through which the beams pass are formed in the blanking plate 20 in such a manner as to correspond to the positions at which the holes H of the shaping aperture array 18 are located. Pairs of electrodes 36 and 37 (blankers B) for blanking deflection are disposed at positions in the vicinity of the passage holes 20a in such a manner that each of the electrodes 36 faces the corresponding electrode 37 with the corresponding passage hole 20a interposed therebetween. For example, a deflection voltage is applied to the electrodes 36, and the electrodes 37 are grounded. Each of the electron beams that pass through the corresponding passage holes 20a is deflected independently by the voltage applied to the corresponding two electrodes 36 and 37.

The multibeams 40a to 40e that have passed through the blanking plate 20 are reduced by the reducing lens 22 and travel toward a center hole formed in the limiting aperture member 24. A beam positioned outside the center hole of the limiting aperture member 24 is blocked by the limiting aperture member 24.

The limiting aperture member 24 blocks beams, each of which has been deflected by a corresponding one of the blankers B of the blanking plate 20 so as to be in a beam-off state. One shot includes beams that have passed through the limiting aperture member 24 during the period from when the beams are brought into a beam-on state until the beams are brought into the beam-off state. The beams, which have passed through the center hole of the limiting aperture member 24, are focused by the objective lens 26 so as to form a pattern image at a desired reduction ratio. Then, the beams are collectively deflected by the deflector 28 in the same direction and are radiated onto desired irradiation positions on the substrate 34.

The alignment portion 21 is disposed between the blanking plate 20 and the reducing lens 22, the alignment portion 21 being formed of a deflection coil used for causing electron beams to be incident so as to match the optical axis of the lens (used for performing optical axis alignment).

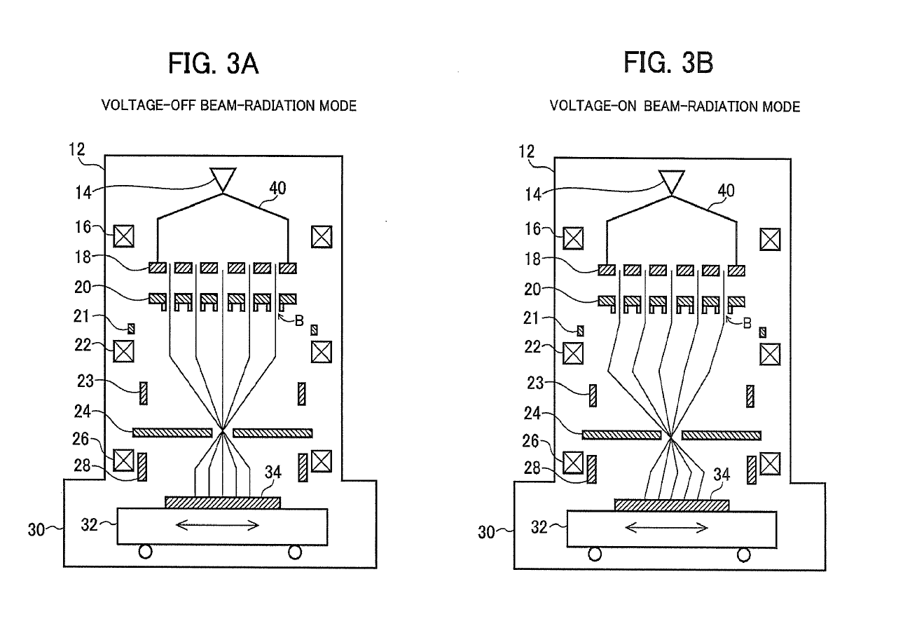

The writing apparatus 1 according to the present embodiment can switch its mode between a voltage-off beam-radiation mode (first writing mode) and a voltage-on beam-radiation mode (second writing mode) by controlling the amount of deflection of electron beams performed by the alignment portion 21. In the voltage-off beam-radiation mode (first writing mode), as illustrated in FIG. 3A, electron beams that have not been deflected by the blankers B of the blanking plate 20 pass through the center hole of the limiting aperture member 24. In the voltage-on beam-radiation mode (second writing mode), as illustrated in FIG. 3B, electron beams that have been deflected by the blankers B of the blanking plate 2 pass through the center hole of the limiting aperture member 24.

In the voltage-off beam-radiation mode, electron beams that have not been deflected by the blankers B of the blanking plate 20 are radiated onto the substrate 34, and electron beams that have been deflected are blocked by the limiting aperture member 24.

In contrast, in the voltage-on beam-radiation mode, electron beams that have been deflected by the blankers B of the blanking plate 20 are radiated onto the substrate 34, and electron beams that have not been deflected by the blankers B are blocked by the limiting aperture member 24.

When the stage 32 is moving continuously, the deflector 28 performs control in such a manner that the irradiation positions of the beams follow the movement of the stage 32. The stage control unit 56 causes the stage 32 to move.

The control computer 52 generates an apparatus-specific shot data by performing data conversion processing having a plurality of steps on writing data. The shot data defines the amount of irradiation, the irradiation position coordinates, and the like of each shot.

The control computer 52 outputs the amount of irradiation of each shot based on the shot data to the deflection control unit 54. The deflection control unit 54 determines an irradiation time t by dividing the amount of irradiation, which has been input thereto, by current density. When a shot is performed, the deflection control unit 54 controls a deflection voltage to be applied to the corresponding blanker B in such a manner that the beams are enabled only during the irradiation time t.

In addition, the control computer 52 outputs deflection-position data to the deflection control unit 54 in such a manner that each of the beams is deflected to the corresponding position (coordinates) represented by the shot data. The deflection control unit 54 calculates an amount of deflection and applies a deflection voltage to the deflector 28. As a result, the multibeams included in the shot are collectively deflected.

In the writing apparatus 1 having the configuration such as that described above, in the case where at least one of the blankers B of the blanking plate 20 has a defect, when writing is performed without taking into consideration the fact that the at least one of the blankers B of the blanking plate 20 has a defect, the writing accuracy deteriorates. Therefore, it is necessary to determine the blanker B that has a defect (a defective portion) and to classify the type of the defect.

Since errors in the shapes of the holes H of the shaping aperture array 18 and the passage holes 20a of the blanking plate 20 also result in deterioration of the writing accuracy, it is necessary to determine a hole having an error in its shape. A method for detecting a defect of the blanking plate 20 and the shaping aperture array 18 will be described below.

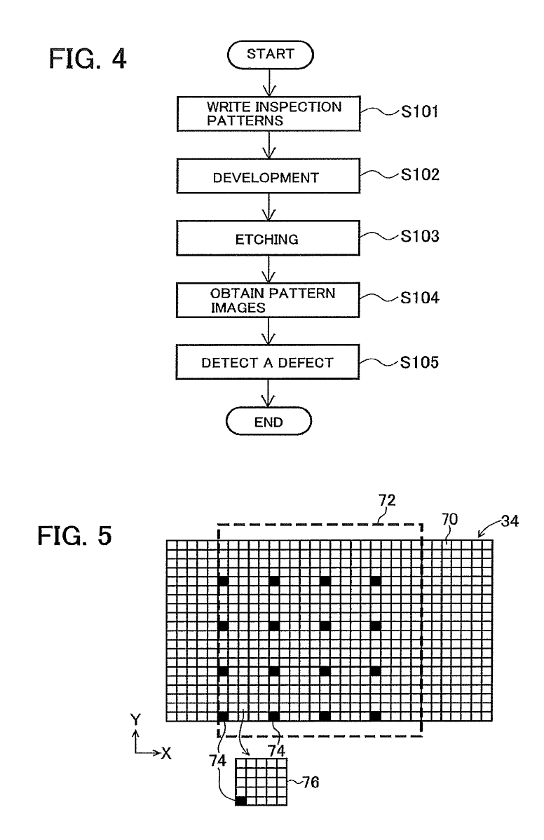

FIG. 4 is a flowchart illustrating a method for inspecting the blanking plate 20 and the shaping aperture array 18. As illustrated in FIG. 4, this method includes a process (step S101) of writing an inspection pattern for defect detection to a resist film on the substrate, a process (step S102) of forming a resist pattern by performing a developing treatment, a process (step S103) of forming an inspection pattern in a light-blocking film by performing an etching operation by using the resist pattern as a mask, a process (step S104) of obtaining a pattern image of the inspection pattern, and a process (step S105) of detecting a defect by performing a die-comparison inspection (die-to-die inspection) and a data-comparison inspection (die-to-database inspection) of the pattern image.

In step S101, an inspection pattern is written by radiating the multibeams onto the substrate 34 for inspection, which has been placed on the stage 32. The substrate 34 for inspection is formed by, for example, stacking a light-blocking film, such as a chromium film, and a resist film on a glass substrate.

FIG. 5 illustrates an example of an irradiation region and writing-target pixels of the multibeams, the multibeams being formed by the shaping aperture array 18 having sixteen holes H arranged in four columns and four rows.

As illustrated in FIG. 5, an inspection-pattern writing region of the substrate 34 is divided into mesh regions having a mesh-like shape, and each of the mesh regions is a writing-target pixel 70 (writing position). In an irradiation region 72 that can be irradiated with the multibeams at a time, a plurality of (sixteen in this example) pixels 74 that can be irradiated with the multibeams at a time are illustrated. The pitch of the adjacent pixels 74 corresponds to the pitch of the beams.

In the example illustrated in FIG. 5, grids 76 are each formed of a square region whose sides in the X direction and the Y direction are each equal to the beam pitch. In the example illustrated in FIG. 5, each of the grids 76 is formed of 5×5 pixels.

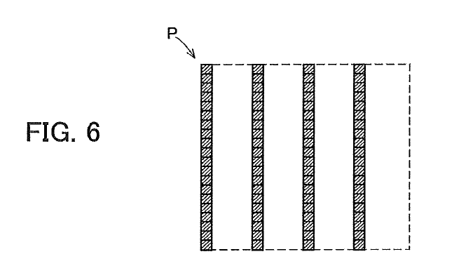

As illustrated in FIG. 6, in each of the grids 76, each five pixels arranged in a line in the Y direction (or the X direction) are irradiated with one of the beams, and a line-and-space pattern P extending in the Y direction (or the X direction) is written. Each of the beams is radiated onto the corresponding five pixels arranged in a line (line piece), and a line pattern is written by connecting adjacent line pieces, which have been irradiated with the corresponding beams, to each other. When writing the line-and-space pattern P that serves as an inspection pattern, the irradiation positions of the multibeams may be moved as a result of being deflected by the deflector 28 or may be moved as a result of the movement of the stage 32.

A plurality of inspection patterns (line-and-space patterns) are written to the substrate 34 while changing a writing mode and a focus (focal position). First, the writing mode is set to the voltage-off beam-radiation mode (first writing mode), and the voltage to be applied to all the blankers B is set to 0 V (no voltage is applied). The focus is set to the best focus, and then, a first inspection pattern is written.

Next, in another region on the substrate 34, the writing mode is set to the voltage-on beam-radiation mode (second writing mode), and a predetermined voltage (e.g., 5 V) is applied to all the blankers B. The focus is set to the best focus, and then, a second inspection pattern is written.

Subsequently, in another region on the substrate 34, the writing mode is set to the voltage-on beam-radiation mode (second writing mode), and a predetermined voltage (e.g., 5 V) is applied to all the blankers B. The focus is defocused from the best focus, and then, a third inspection pattern is written. The focus may be changed as a result of the objective lens 26 being adjusted or may be changed as a result of the height (the position in the Z direction) of the substrate 34 being changed by driving the stage 32. The first to third inspection patterns may be written in any order.

After the first to third inspection patterns have been written, the resist film to which the electron beams have been radiated is developed by using a developing device and a developing solution, which are commonly known (step S102). In the resist film, portions to which the electron beams have been radiated are solubilized with respect to the developing solution, and a resist pattern is formed.

After that, an etching operation is performed, by using the resist pattern as a mask, on the light-blocking film whose surface is exposed (step S103). As a result, the light-blocking film is processed, and a line-and-space inspection pattern is formed. After the etching operation has been performed, the resist pattern is removed by ashing or the like.

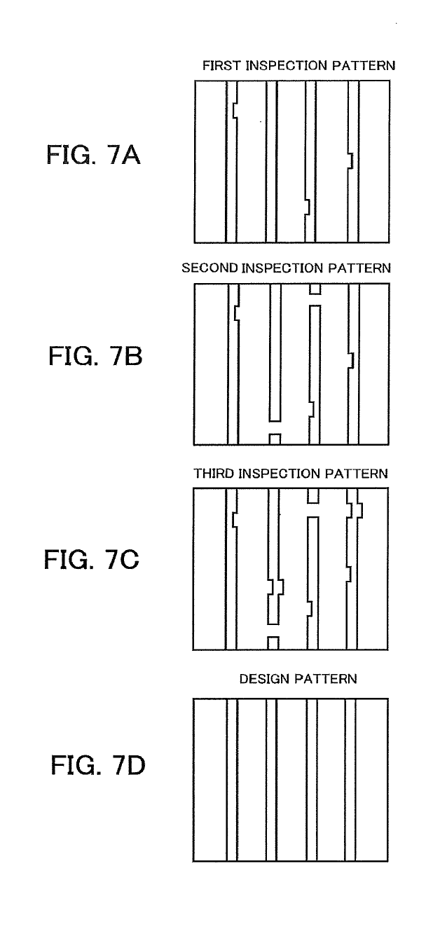

A pattern image of an inspection pattern is obtained by using an inspection apparatus, such as an SEM (step S104). For example, pattern images of the first to third inspection patterns such as those illustrated in FIG. 7A to FIG. 7C are obtained. FIG. 7D illustrates a pattern (design pattern) based on design data.

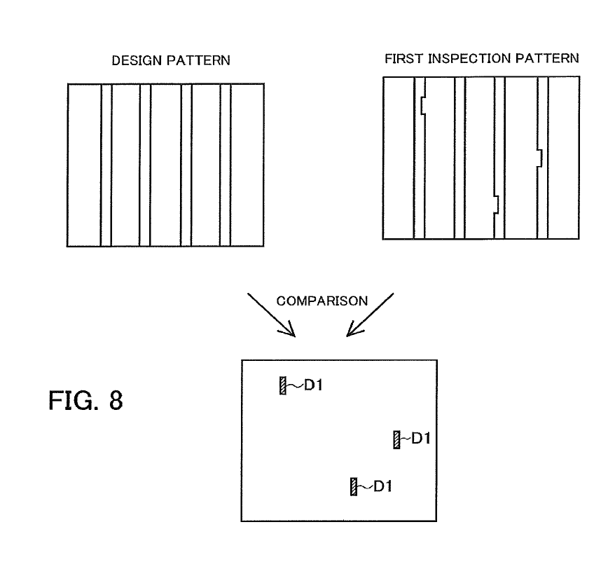

A defect is detected by comparing pattern images (step S105). For example, differences D1 such as those illustrated in FIG. 8 are obtained by performing a comparison inspection (die-to-database inspection) of the pattern image of the first inspection pattern (first pattern image) with the design pattern. It is determined that the holes H of the shaping aperture array 18 or the passage holes 20a of the blanking plate 20 located at the positions corresponding to the differences D1 each have a defect (an error in shape). As described above, by performing a comparison inspection of the first inspection pattern and the design pattern, a defect related to errors in the shapes of the holes H of the shaping aperture array 18 or the passage holes 20a of the blanking plate 20 is detected.

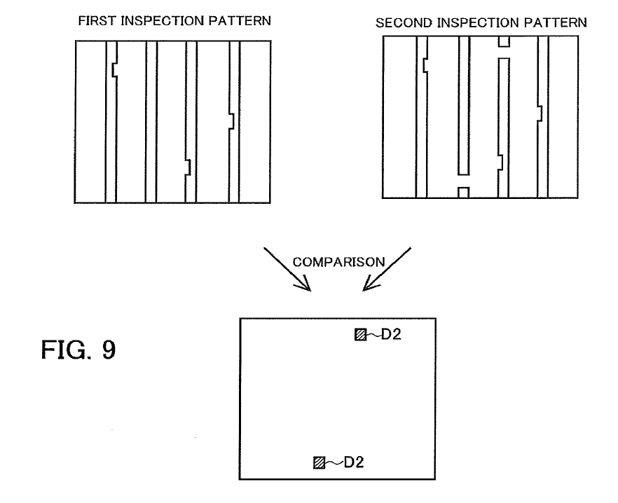

Differences D2 such as those illustrated in FIG. 9 are obtained by performing a comparison inspection (die-to-die inspection) of the first inspection pattern and the second inspection pattern. The first inspection pattern and the second inspection pattern have been written by using the electron beams in different writing modes.

The first inspection pattern has been written in the voltage-off beam-radiation mode (first writing mode), which is illustrated in FIG. 3A, while the voltage applied to all the blankers B of the blanking plate 20 was set to 0 V. In the voltage-off beam-radiation mode, electron beams that are not deflected by the blankers B are radiated onto the substrate 34, and thus, all the beams are radiated onto the substrate 34 even in the case where there is a blanker B to which the deflection voltage cannot be applied.

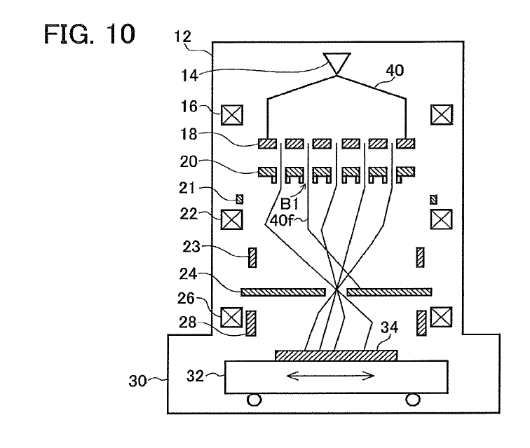

In contrast, the second inspection pattern has been written in the voltage-on beam-radiation mode (second writing mode), and the electron beams that are deflected by the blankers B are radiated onto the substrate 34. As illustrated in FIG. 10, in the case where there is a blanker B1 to which the deflection voltage cannot be applied, an electron beam 40f that has not been deflected is blocked by the limiting aperture member 24 and will not be radiated onto the substrate 34.

Thus, it is determined that the blankers B of the blanking plate 20, which are located at the positions corresponding to the differences D2 between the first inspection pattern and the second inspection pattern, each have a defect because of which a voltage cannot be applied to the blanker B.

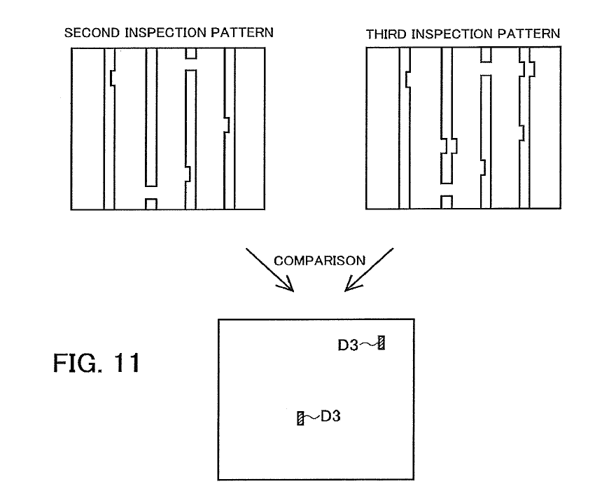

Differences D3 such as those illustrated in FIG. 11 are obtained by performing a comparison inspection (die-to-die inspection) of the second inspection pattern and the third inspection pattern. The second inspection pattern and the third inspection pattern have been written by using the electron beams at different focuses.

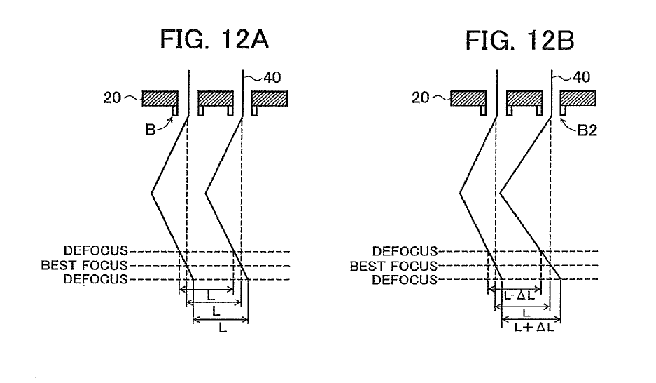

The second inspection pattern and the third inspection pattern have been written in the voltage-on beam-radiation mode (second writing mode), in which the electron beams deflected by the blankers B of the blanking plate 20 are radiated onto the substrate 34. In this mode, in the case where a desired deflection voltage is applied to the blankers B, as illustrated in FIG. 12A, the distance (beam gap) L between adjacent beams on the substrate 34 does not vary with a change in the focus.

However, as illustrated in FIG. 12B, in the case where there is a blanker B2 to which a desired deflection voltage cannot be applied (deviation has occurred in the applied voltage), when a difference in the deflection amount and a difference in the focus (focal position) occur, a difference ΔL occurs in the distance (beam gap) between adjacent beams on the substrate 34.

Therefore, it is determined that the blankers B of the blanking plate 20, which are located at the positions corresponding to the differences D3 between the second inspection pattern and the third inspection pattern, each have a defect because of which a predetermined deflection voltage cannot be applied to the blanker B (the applied voltage is deviated from a predetermined value).

As described above, the first to third inspection patterns are formed by changing the writing mode and the focus when writing the patterns, and a die-comparison inspection (die-to-die inspection) and a data-comparison inspection (die-to-database inspection) are performed, so that a defective portion of the blanking plate 20 or the shaping aperture array 18 can be detected (determined). In addition, a defect, which has been detected, can be classified as an error in the shape of one of the holes H of the shaping aperture array 18 or one of the passage holes 20a of the blanking plate 20, an error in the operation of one of the blankers B of the blanking plate 20, or deviation of the voltage applied to the blankers B from a predetermined value. It is not necessary to determine a defective portion from the writing result of each beam, and defect inspection can be effectively performed with high accuracy.

In the above-described embodiment, a plurality of third inspection patterns may be written by varying the amount of change in the focus. For example, two types of third inspection patterns may be written, which are a third inspection pattern written by defocusing the focus from the best focus toward the positive side and a third inspection pattern written by defocusing the focus from the best focus toward the negative side, may be written. Even in the case where deviation has occurred in the best focus, a difference D3 between one of the third inspection patterns and the second inspection pattern explicitly occurs, and the accuracy with which defect inspection is performed can be improved.

In the above-described embodiment, although the case where a line-and-space pattern is formed as an inspection pattern has been described, the shape of the inspection pattern is not limited to this, and the inspection pattern may be, for example, a contact hole.

In the above-described embodiment, although the configuration in which electron beams are radiated has been described, other charged particle beams, such as ion beams, may be radiated.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method for inspecting a blanking plate, the method including:
generating a plurality of beams by causing a charged particle beam to pass through a shaping aperture array having a plurality of holes;
performing blanking deflection on the plurality of beams by using a plurality of blankers provided in a blanking plate, each of the plurality of blankers corresponding to one of the plurality of beams;
writing a first inspection pattern on a substrate by using a first writing mode in which beams that have not been deflected by the plurality of blankers are radiated onto the substrate;
writing a second inspection pattern on the substrate by using a second writing mode in which beams that have been deflected by the plurality of blankers are radiated onto the substrate;
obtaining a pattern image of the first inspection pattern and a pattern image of the second inspection pattern, the first and second inspection patterns having been formed on the substrate; and
determining a defect by comparing the obtained pattern images.

2. The method according to claim 1,
wherein a defect is determined by comparing the pattern image of the first inspection pattern with a design pattern.

3. The method according to claim 1,
wherein a third inspection pattern is written to the substrate by using the second writing mode at a focus different from a focus at which the second inspection pattern is written, and
wherein a defect is determined by comparing the pattern image of the second inspection pattern with a pattern image of the third inspection pattern.

4. The method according to claim 3,
wherein a plurality of the third inspection patterns are written by changing a focus.

5. The method according to claim 4,
wherein the third inspection patterns are written by defocusing a focus from a best focus toward a positive side and by defocusing the focus from the best focus toward a negative side.

6. The method according to claim 1,
wherein the first inspection pattern and the second inspection pattern are each a line-and-space pattern.

7. The method according to claim 6,
wherein line pieces are each written by one of the beams, and
wherein a line pattern is written by connecting the line pieces, which have been written by the beams adjacent to one another.
